(19) United States
(12) Patent Application Publication
(10) Pub. No.: US 2014/0011025 A1
(43) Pub. Date: Jan. 9, 2014

(54) ADHESIVE TAPE FOR PROCESSING SEMICONDUCTOR WAFER ETC

(71) Applicants: Akihiro Ishiba, Amagasaki-shi (JP); Masatoshi Isobe, Amagasaki-shi (JP); Yoshinori Nagao, Amagasaki-shi (JP)

(72) Inventors: Akihiro Ishiba, Amagasaki-shi (JP); Masatoshi Isobe, Amagasaki-shi (JP); Yoshinori Nagao, Amagasaki-shi (JP)

(73) Assignee: SUMITOMO BAKELITE CO., LTD., Shinagawa-ku, Tokyo (JP)

(21) Appl. No.: 14/006,186

(22) PCT Filed: Mar. 27, 2012
(86) PCT No.: PCT/JP2012/057952

§ 371 Date: Sep. 19, 2013

(30) Foreign Application Priority Data
Mar. 30, 2011 (JP) 2011075003
Jan. 11, 2012 (JP) 2012003125

(51) Int. Cl. H01L 21/683

(52) U.S. Cl. CPC H01L 21/6836
USPC 428/355 AC

(57) ABSTRACT

An object of the present invention is to provide an adhesive tape for processing semiconductor wafers and the like that is able to adequately reduce the amount of adhesive remaining on the surface of an adherend after peeling off the tape. The adhesive tape for semiconductor wafer processing (100) according to the present invention comprises a base material layer (200) and an adhesive layer (300). The adhesive layer (300) is formed on at least one side of the base material layer (200). In addition, the adhesive layer (300) is mainly composed of a carboxyl group-containing polymer. The carboxyl group-containing polymer contains a radiation-polymerizable compound (and particularly, urethane acrylate).

### TECHNICAL FIELD

The present invention relates to adhesive tape for use in applications including processing of semiconductor wafers and the like.

The present application claims priority on the basis of Japanese Patent Application No. 2011-075003, filed in Japan on Mar. 30, 2011, and Japanese Patent Application No. 2012-003125, filed in Japan on Jan. 11, 2012, the contents of which are incorporated herein by reference.

### BACKGROUND ART

Various adhesive tapes for processing semiconductor wafers and the like used for dicing semiconductor wafers and packages (to be referred to as “dicing tape”) have been proposed in the past. In general, dicing tape has an adhesive layer formed on a base material layer (base layer), and the semiconductor wafer and the like is fixed by this adhesive layer. Following dicing of a semiconductor wafer and the like, a radiation-polymerizable compound (photocurable resin), a radiation polymerization initiator (photopolymerization initiator) and a crosslinking agent and the like are normally added to the adhesive layer so as to be able to easily pick up the semiconductor chips. In other words, when the adhesive layer is irradiated with radiation (light) such as ultraviolet light following dicing, these components are cured, the adhesiveness of the adhesive layer decreases, and the semiconductor chips can be easily picked up.

However, in the step for separating dicing tape from an adherend, the problem of so-called adhesive deposit occurs in which a portion of the adhesive that composes the adhesive layer remains on the surface of the adherend. In addition, in the step for holding the adherend with dicing tape, there is the problem of the dicing tape being unable to stably hold an adherend having an irregular surface. Therefore, Patent Documents 1 and 2, for example, disclose dicing tape in which the materials of the adhesive layer have been suitably selected in order to solve the aforementioned problems. These dicing tapes are able to stably hold adherends having an irregular surface.

### PRIOR ART DOCUMENTS

### Patent Documents

Patent Document 1: Japanese Unexamined Patent Application, First Publication No. 2005-136298
Patent Document 2: Japanese Unexamined Patent Application, First Publication No. 2003-105283

### DISCLOSURE OF THE INVENTION

### Problems to be Solved by the Invention

However, these dicing tapes were unable to adequately reduce the amount of adhesive remaining on the surface of the adherend after peeling off the tape.

An object of the present invention is to provide an adhesive tape for processing semiconductor wafers and the like that is able to reduce the amount of adhesive remaining on the surface of an adherend after peeling off the tape.

### Means for Solving the Problems

This object is achieved by the present inventions described in (1) to (9) below.

(1) An adhesive tape for semiconductor wafer processing, comprising a base material layer and an adhesive layer formed on at least one side of the base material layer, wherein the adhesive layer contains a carboxyl group-containing polymer, a radiation-polymerizable compound and a crosslinking agent, the weight average molecular weight of the radiation-polymerizable compound is 500 or more and 20000 or less, the number of functional groups of the radiation-polymerizable compound is 5 or more, and the content of the crosslinking agent is 3 parts by weight to 14 parts by weight based on 100 parts by weight of the carboxyl group-containing polymer.

(2) The adhesive tape for semiconductor wafer processing described in (1) above, wherein the weight average molecular weight of the radiation-polymerizable compound is 1000 or more and 20000 or less, and the number of functional groups is 10 or more.

(3) The adhesive tape for semiconductor wafer processing described in (1) or (2) above, wherein the carboxyl group-containing polymer further contains ester group, and the ratio of the number of ester groups to the number of carboxyl groups in the carboxyl group-containing polymer (ester groups/carboxyl groups) is 80/20 to 95/5.

(4) The adhesive tape for semiconductor wafer processing described in any one of (1) to (3) above, wherein the weight average molecular weight of the radiation-polymerizable compound is 500 to 3000 and the number of functional groups is 15 or less.

(5) The adhesive tape for semiconductor wafer processing described in any one of (1) to (4), wherein the functional groups are vinyl groups.

(6) The adhesive tape for semiconductor wafer processing described in any one of (1) to (5), wherein the content of the radiation-polymerizable compound is 30 parts by weight to 70 parts by weight based on 100 parts by weight of the carboxyl group-containing polymer.

(7) The adhesive tape for semiconductor wafer processing described in anyone of (1) to (6) above, wherein the radiation-polymerizable compound is urethane acrylate.

(8) The adhesive tape for semiconductor wafer processing described in any one of (1) to (7) above, wherein the crosslinking agent contains an isocyanate group.

(9) The adhesive tape for semiconductor wafer processing described in any one of (1) to (8) above, wherein the carboxyl group-containing polymer is a copolymer of an acrylic acid ester and acrylic acid.

As a result of being provided with the aforementioned constitution, the adhesive tape for semiconductor wafer processing according to the present invention is able to more stably hold an adherend having an irregular surface.

In addition, an object of the dicing tape according to the present invention is to demonstrate favorable adhesive strength with respect to an adherend and improve pickup, and employs a structure in which a die attach film and the like is not provided on an adhesive layer.

As a result of employing such a structure, it is not necessary to consider the problems described in (I) to (IV) below that occur in the case of laminating a die attach film and the like on an adhesive layer.

(I) The quality of cut products decreases due to melting of the die attach film during dicing and pickup decreases due to adhesion between the adhesive layer and die attach film. (II) Pickup decreases during long-term storage due to adhesion between the die attach film and adhesive layer. (III) The number of production steps increases due to lamination of the die attach film. (IV) Normal-temperature transport is not possible due to the potential for reaction between the die attach film and the adhesive layer.

### Effects of the Invention

The adhesive tape for semiconductor wafer processing according to the present invention is able to reduce the amount of adhesive remaining on the surface of an adherend after peeling off the tape.

### BRIEF DESCRIPTION OF THE DRAWINGS

FIG. 1 is a cross-sectional view of dicing tape according to an embodiment of the present invention.

### BEST MODE FOR CARRYING OUT THE INVENTION

The following provides a detailed explanation of the adhesive tape for semiconductor wafer processing of the present invention based on concrete embodiments thereof.

The adhesive tape for semiconductor wafer processing of the present invention comprises a base material layer and an adhesive layer formed on at least one side of the aforementioned base material layer, the adhesive layer contains a carboxyl group-containing polymer and a radiation-polymerizable compound, the weight average molecular weight of the radiation-polymerizable compound is 500 to 3000, and the number of functional groups of the radiation-polymerizable compound is 5 to 15.

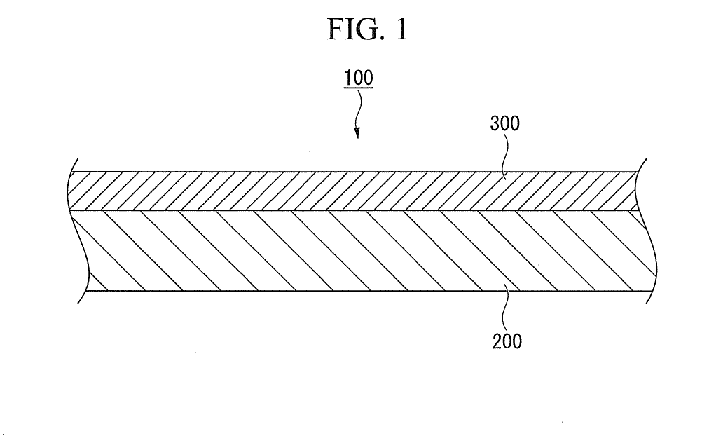

FIG. 1 is a drawing for explaining an embodiment of the adhesive tape 100 for semiconductor wafer processing of the present invention (to also be referred to as “adhesive tape” or “dicing tape”). As shown in FIG. 1, an adhesive tape 100 according to an embodiment of the present invention is composed by containing a base material layer 200 and an adhesive layer 300. The following provides detailed explanations of the base material layer 200 and the adhesive layer 300, respectively, in the case of using the adhesive tape as dicing tape.

<Base Material Layer (Base Layer)>

The base material layer 200 mainly contains a material resin and plays the role of supporting the adhesive layer 300. In addition, this base material layer 200 has just enough strength to be able to withstand stretching in an expanding step carried out after the dicing step. The expanding step is a step for stretching the adhesive tape 100 to expand the interval between chips. The purpose of this expanding step is to enhance chip recognition during pickup and prevent damage to a device caused by contact between adjacent chips.

The aforementioned material resin is formed into a film by an ordinary film forming method. There are no particular limitations on this material resin provided it is permeable to radiation (such as visible light, near infrared light, ultraviolet light, X-rays or an electron beam), and examples of material resins used include polyolefin-based resins such as polyvinyl chloride, polyethylene, polypropylene, polybutene, polybutadiene or polymethylpentene, olefin-based copolymers such as ethylene-vinyl acetate copolymer, ionomer, ethylene-(meth)acrylic acid copolymer or ethylene-(meth)acrylic acid ester copolymer, polyalkylene terephthalate-based resins such as polyethylene terephthalate or polybutylene terephthalate, thermoplastic resins such as styrene-based thermoplastic elastomer, olefin-based thermoplastic elastomer, polyvinyl isoprene or polycarbonate, and mixtures of these thermoplastic resins.

Mixtures of polypropylene and an elastomer or mixtures of polyethylene and an elastomer are used particularly preferably for the material resin. In addition, this elastomer is preferably a block copolymer containing a polystyrene segment represented by general formula (1) and a vinyl polyisoprene segment represented by general formula (2). In addition, a polyisoprene segment hydrogenated is preferable from the viewpoint of weather resistance.

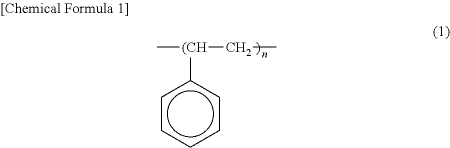

(In formula (1), n represents an integer of 2 or more.)

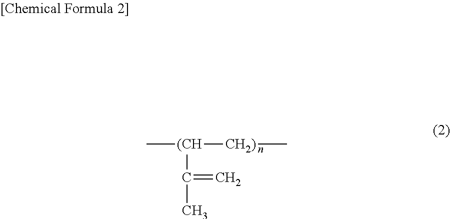

(In formula (2), n represents an integer of 2 or more.)

Although there are no particular limitations thereon, the thickness of the aforementioned base material layer 200 is preferably 50 μm to 300 μm and more preferably 80 μm to 200 μm. If the thickness of the base material layer 200 is within the aforementioned ranges, it may be superior in terms of cost and from the viewpoint of workability in the dicing step or expanding step.

Although there are no particular limitations on the production method of the aforementioned base material layer 200, an ordinary molding method such as calendering or extrusion molding is used. A functional group that reacts with a material that composes the adhesive layer 300, such as a hydroxyl group or amino group, is preferably exposed on the surface of the aforementioned base material layer 200. In addition, the surface of the base material layer 200 is preferably subjected to surface treatment such as corona treatment or anchor coating in order to improve adhesion between the base material layer 200 and the adhesive layer 300.

<Adhesive Layer>

The adhesive layer 300 plays the role of adhering and holding an adherend in the form of a semiconductor wafer and the like in the dicing step. When this adhesive layer 300 is irradiated with radiation (light) after the dicing step, cut pieces of the semiconductor wafer and the like can be separated easily. Furthermore, the adhesive layer 300 is normally protected with a release film in the adhesive tape 100 prior to use.

The aforementioned adhesive layer 300 is formed on at least one side of the base material layer 200 (see FIG. 1) Furthermore, the material of the adhesive layer 300 in the form of a resin solution is normally coated onto the base material layer 200 by a coating method such as die coating, curtain die coating, gravure coating, comma coating, bar coating or lip coating. Although there are no particular limitations on the thickness of the adhesive layer 300 after drying, it is preferably 5 μm to 30 μm and more preferably 10 μm to 25 μm. The adhesive layer demonstrates superior power of holding the adherend by making the thickness of the adhesive layer after drying to be equal to or greater than the lower limit values of the aforementioned ranges. In addition, a dicing film that is superior in terms of cost and preventing the problem of adhesive fragments adhering to the chips during dicing is obtained by making the thickness of the adhesive layer after drying to be equal to or less than the upper limit values of the aforementioned ranges.

The aforementioned adhesive layer 300 contains a carboxyl group-containing polymer. In addition, the adhesive layer 300 contains a radiation-polymerizable compound (curing component that causes curing of the adhesive layer 300). Furthermore, an antistatic agent or tackifier and the like may also be included as arbitrary components in this adhesive layer 300. The following provides detailed descriptions of each component.

(1) Carboxyl Group-Containing Polymer

Although examples of the carboxyl group-containing polymer include copolymers of an addition-type monomer having carboxyl group and acrylic acid ester, vinyl acetate, acrylonitrile or styrene, among these, a copolymer of an addition-type monomer having carboxyl group and an acrylic acid ester, namely a carboxyl group-containing acrylic polymer containing ester group, is particularly preferable. The ratio of the number of ester groups to the number of carboxyl groups (ester groups/carboxyl groups) of this carboxyl group-containing polymer containing ester group is preferably 80/20 to 95/5, more preferably 85/15 to 95/5, and even more preferably 85/15 to 90/10. As a result of making the ratio of the number of ester groups to the number of carboxyl groups (ester groups/carboxyl groups) of this carboxyl group-containing polymer containing ester group to be within the aforementioned ranges, the adhesive tape for semiconductor wafer processing is able to more easily follow the surface and is able to be stably held on the surface of the adherend having an irregular surface. Furthermore, at least one of a vinyl acetate monomer and addition-type monomer having a functional group other than a carboxyl group may also be copolymerized in this carboxyl group-containing acrylic polymer within a range that does not impair the gist of the present invention.

Examples of the aforementioned addition-type monomer having a carboxyl group include methacrylic acid, acrylic acid, itaconic acid and maleic anhydride. Examples of acrylic acid esters include ethyl acrylate, butyl acrylate, 2-ethylhexyl acrylate, glycidyl acrylate, 2-hydroxyethyl acrylate, ethyl methacrylate, butyl methacrylate, 2-ethylhexyl methacrylate, glycidyl methacrylate, 2-hydroxyethyl methacrylate and dimethylaminoethyl methacrylate. Among these, at least one type of acrylic acid ester selected from the group consisting of ethyl acrylate, butyl acrylate, 2-ethylhexyl acrylate and dimethylaminoethyl methacrylate is preferable. The use of an acrylic acid ester having carboxyl group is particularly preferable for mounting a semiconductor member and inhibiting scattering of end materials and chipping in order to improve adhesion with the adherend.

In addition, there are no particular limitations on the addition-type monomer having a functional group other than carboxyl group, and examples thereof include hydroxyethyl methacrylate, hydroxyethyl acrylate, hydroxypropyl methacrylate, hydroxypropyl acrylate, dimethylaminoethyl methacrylate, dimethylaminoethyl acrylate, acrylamide, methylol acrylamide and glycidyl methacrylate.

For example, an acrylic resin represented by the following chemical structural formula (3), namely a copolymer of addition-type monomers having carboxyl group in the form of acrylic acid and acrylic acid esters in the form of 2-ethylhexyl acrylate, is used for the carboxyl group-containing acrylic polymer. In this chemical structural formula, n preferably represents a molar equivalent of 85 parts by weight to 95 parts by weight, and m preferably represents a molar equivalent of 5 parts by weight to 15 parts by weight. If the value of m is lower than the aforementioned range, the ability to follow the irregularities on the surface of the adherend becomes poor, resulting in the risk of the chips scattering or cutting fluid penetrating into the back of the chip during dicing, while if the value of m exceeds the aforementioned range, adhesion between the adhesive layer and the adherend becomes excessive, thereby resulting in the risk of the occurrence of problems with pickup. Among the aforementioned ranges, n is more preferably the molar equivalent of 90 parts by weight, and m is more preferably the molar equivalent of 10 parts by weight.

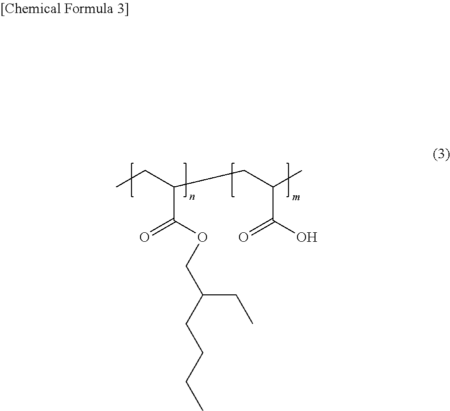

(2) Radiation-Polymerizable Compound (UV-Curable Resin, Curing Component)

The radiation-polymerizable compound is used as a curing component that causes curing of the adhesive layer 300, and although examples of the aforementioned radiation-polymerizable compound include monofunctional acrylates, polyfunctional acrylates, monofunctional methacrylates, polyfunctional methacrylates, urethane acrylate, urethane methacrylate, epoxy acrylate, epoxy methacrylate, polyester acrylate and urea acrylate, urethane acrylate is preferable among them. This is because cracking of the adhesive by a needle during pickup can be reduced due to the toughness and flexibility of the backbone structure of urethane acrylate. In addition, urethane acrylate is cured when irradiated with ultraviolet light. Adhesive strength of the adhesive layer 300 decreases as a result of a base resin being incorporated in the crosslinked structure of urethane acrylate by this curing. Furthermore, other curing components may also be used together with urethane acrylate within a range that does not impair the gist of the present invention, examples of which include trimethylolpropane triacrylate, tetramethylolmethane tetraacrylate, pentaerythritol triacrylate, pentaerythritol tetraacrylate, dipentaerythritol monohydroxy pentaacrylate, dipentaerythritol hexaacrylate, 1,4-butylene glycol diacrylate, 1,6-hexanediol diacrylate, polyethylene glycol diacrylate and commercially available oligoester acrylates.

The weight average molecular weight of the aforementioned radiation-polymerizable compound (and particularly, urethane acrylate) is 500 or more, preferably 700 or more, more preferably 1000 or more, and even more preferably 1200 or more. In addition, the weight average molecular weight thereof is 20000 or less, preferably 3000 or less, even more preferably 2500 or less and most preferably 2000 or less. If the weight average molecular weight of the radiation-polymerizable compound is less than 500, the adhesive is susceptible to scattering during dicing resulting in the risk of contamination of the chip surface, while there is also the risk of increased susceptibility to adhesive transfer to the adherend, thereby making this undesirable. If the weight average molecular weight of the aforementioned polymerizable compound exceeds 20000, the amount of adhesive composing the adhesive layer 300 that remains on the surface of the adherend after peeling off the radiation tape cannot be adequately reduced, while there is also the risk of being unable to obtain adequate adhesive strength with respect to the adherend. In addition, when considering decrease of the ability to follow the irregularities on the surface of the adherend and decrease of the probability of chip scattering and penetration of cutting fluid into the back of the chip during dicing, the weight average molecular weight of the radiation-polymerizable compound is preferably 3000 or less.

An example of a method used to measure the weight average molecular weight of the aforementioned radiation-polymerizable compound (and particularly, urethane acrylate) is gel chromatography (abbreviated as GPC). Although there are no particular limitations on measurement by the aforementioned GPC, measurement was carried out using the Alliance System manufactured by Waters Corp. (consisting of the 2695 Separations Module, 2414 Refractive Index Detector, TSK Gel GMHHR-L×2+TSK Guard Column HHR-L×1, and THF at 1.0 ml/min for the mobile phase) under conditions of a column temperature of 40.0° C., internal differential refractometer temperature of 40.0° C. and sample injection volume of 100 μL.

In addition, the number of functional groups of the aforementioned radiation-polymerizable compound (and particularly, urethane acrylate) is 5 or more, preferably 7 or more, more preferably 8 or more and even more preferably 10 or more. The number of functional groups is 15 or less, preferably 13 or less and more preferably 12 or less. In the case the number of functional groups of the radiation-polymerizable compound is less than 5, curing after irradiating with radiation becomes inadequate, and there is the risk of the occurrence of problems with pickup. In the case of the number of functional groups of the radiation-polymerizable compound exceeds 15, slack forms in the tape due to cure shrinkage, resulting in the risk of the occurrence of problems with chipping and pickup. In addition, excessive curing causes the adhesive to become brittle, thereby resulting in the risk of the problem of adhesive fragments adhering to the back of the chip during pickup.

As a result of making the weight average molecular weight of the aforementioned radiation-polymerizable compound (and particularly, urethane acrylate) to be 500 to 3000 and the number of functional groups to be 5 to 15, the adhesive tape for semiconductor wafer processing according to the present invention makes it possible to adequately reduce the amount of adhesive that composes the adhesive layer 300 remaining on the surface of the adherend after peeling off the tape, while also having adequate adhesive strength with respect to the adherend. In addition, the adhesive tape also has favorable mountability and pickup, and is able to stably hold the adherend having an irregular surface.

Furthermore, the aforementioned functional groups of the aforementioned radiation-polymerizable compound are preferably vinyl groups.

The content of the aforementioned radiation-polymerizable compound (and particularly, urethane acrylate) is 30 parts by weight to 70 parts by weight, preferably 40 parts by weight to 60 parts by weight and more preferably 45 parts by weight to 55 parts by weight based on 100 parts by weight of the aforementioned carboxyl group-containing polymer. Pickup of the adhesive tape 100 is favorable as a result of making the content of the radiation-polymerizable compound to be within the aforementioned ranges.

The aforementioned curing component is preferably used with a radiation polymerization initiator and crosslinking agent within a range that does impair the gist of the present invention.

The aforementioned radiation polymerization (photopolymerization) initiator is added to facilitate initiation of polymerization of the curing component. Examples of radiation polymerization initiators include 2,2-dimethoxy-1,2-diphenylethane-1-one, benzophenone, acetophenone, benzoin, benzoin methyl ether, benzoin ethyl ether, benzoin isopropyl ether, benzyldiphenyl sulfide, tetramethylthiuram monosulfide, azobisisobutyronitrile, dibenzyl, diacetyl and β-chloroanthraquinone.

Examples of the aforementioned crosslinking agent include epoxy-based crosslinking agents, isocyanate-based crosslinking agents, methylol-based crosslinking agents, chelate-based crosslinking agents, aziridine-based crosslinking agents, melamine-based crosslinking agents and polyvalent metal chelate-based crosslinking agents. Among these, isocyanate-based crosslinking agents are used preferably based on their high productivity (pot life) and low level of impurities.

There are no particular limitations on the aforementioned isocyanate-based crosslinking agents, and examples thereof include polyisocyanate compounds of polyvalent isocyanates, trimers of polyisocyanate compounds, trimers of terminal isocyanate compounds obtained by reacting polyisocyanate compounds and polyol compounds, and blocked polyisocyanate compounds obtained by sealing a terminal isocyanate urethane prepolymer with a phenol or oxime and the like. Among these, polyvalent isocyanates are used preferably from the viewpoint of allowing the formation of a suitably crosslinked network. This is because the crosslinking of polyvalent isocyanates makes it possible to enhance cohesion of the adhesive layer and inhibit adhesive deposit to the adherend.

Examples of the aforementioned polyvalent isocyanates used include 2,4-tolylene diisocyanate, 2,6-tolylene diisocyanate, 1,3-xylylene diisocyanate, 1,4-xylylene diisocyanate, diphenylmethane-4,4′-diisocyanate, diphenylmethane-2,4′-diisocyanate, 3-methyldiphenylmethane diisocyanate, hexamethylene diisocyanate, isophorone diisocyanate, dicyclohexylmethane-4,4′-diisocyanate and dicyclohexylmethane-2,4′-diisocyanate. Among these, at least one type of polyvalent isocyanate selected from the group consisting of 2,4-tolylene diisocyanate, diphenylmethane-4,4′-diisocyanate and hexamethylene diisocyanate is exemplified.

The aforementioned adhesive layer 300 preferably contains 3 parts by weight to 14 parts by weight of crosslinking agent, more preferably 4 parts by weight to 10 parts by weight of the crosslinking agent, and even more preferably 5 parts by weight to 7 parts by weight of the crosslinking agent based on 100 parts by weight of the carboxyl group-containing polymer. As a result of the crosslinking agent being contained within the aforementioned ranges, the adhesive tape for semiconductor wafer processing according to the present invention is able to adequately reduce the amount of adhesive remaining on the surface of the adherend after peeling off the tape, while also having adequate adhesive strength with respect to the adherend. Moreover, the adhesive tape for semiconductor wafer processing according to the present invention also has favorable pickup.

(3) Antistatic Agent

There are no particular limitations on the antistatic agent, and examples of antistatic agents used include surfactants such as anionic surfactants, cationic surfactants, nonionic surfactants and amphoteric surfactants. In addition, powders of carbon black, silver, nickel, antimony-doped tin oxide or tin-doped indium oxide, for example, are used as antistatic agents that have no temperature dependence.

(4) Tackifier

There are no particular limitations on the tackifier, and examples of tackifiers used include rosin resin, terpene resin, coumarone resin, phenol resin, styrene resin, aliphatic petroleum resins, aromatic petroleum resins and aliphatic/aromatic copolymer-based petroleum resins.

Examples of applications of the adhesive tape for semiconductor wafer processing of the present invention include, in addition to dicing tape, electronics applications such as back grinding tape or printed board protective tape, window glass protective film, decorative marking film and base materials for medical and sanitary pharmaceuticals.

<Adhesive Tape (Dicing Tape) Usage Method>

A known method can be used for using the adhesive tape 100. For example, after attaching and fixing the adhesive tape 100 to an adherend in the form of a semiconductor wafer and the like, the semiconductor device is cut into individual elements with a rotary slicer. After cutting, the adhesive tape 100 is irradiated with ultraviolet light from the side of the base material layer 200. Following irradiation, after expanding the adhesive tape 100 radially using a special jig to increase the interval between chips to a constant interval, the semiconductor devices are pushed up with a needle and the like. After having been pushed up, the semiconductor devices are picked up by suctioning with a vacuum collet or air pincette, followed by mounting or housing in a tray.

### EXAMPLES

The following provides an explanation of Examples 1 to 7 and Comparative Examples 1 to 5 according to the adhesive tape 100 of the present invention. Furthermore, the present invention is not limited by these examples.

### Example 1

### Production of Dicing Tape

60 parts by weight of polypropylene and 40 parts by weight of a block copolymer comprising a polystyrene segment represented by general formula (1) and a vinyl polyisoprene segment represented by general formula (2) were prepared for use as the material that composes the base material layer 200.

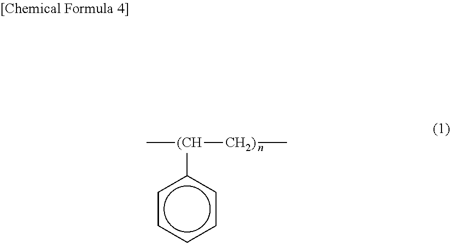

(In formula (1), n represents an integer of 2 or more.)

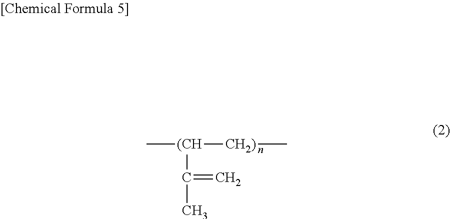

(In formula (2), n represents an integer of 2 or more.)

After kneading the aforementioned materials composing the base material layer 200 with a biaxial kneader, the kneaded mixture was extruded with an extruder to produce the base material layer 200 having a thickness of 150 μm.

A carboxyl group-containing acrylic polymer was prepared for use as the carboxyl group-containing polymer of the adhesive layer 300. The carboxyl group-containing acrylic polymer was obtained by solution polymerization of 90% by weight of butyl acrylate and 10% by weight of acrylic acid in toluene solvent in accordance with routine methods. This carboxyl group-containing acrylic polymer is a resin having a weight average molecular weight of 600,000, and the ratio of the number of ester groups to the number of carboxyl groups (ester groups/carboxyl groups) was 90/10.

50 parts by weight of urethane acrylate having a weight average molecular weight of 1400 and 9 functional groups (trade name: UA-33H, Shin-Nakamura Chemical Co., Ltd.) were prepared based on 100 parts by weight of the carboxyl group-containing polymer for use as the curing component of the adhesive layer 300. Weight average molecular weight was measured by GPC by dissolving 20 mg of the urethane acrylate in 6 ml of tetrahydrofuran (THF). GPC measurement was carried out using the Alliance System manufactured by Waters Corp. (consisting of the 2695 Separations Module, 2414 Refractive Index Detector, TSK Gel GMHHR-L×2+TSK Guard Column HHR-L×1, and THF at 1.0 ml/min for the mobile phase) under conditions of a column temperature of 40.0° C., internal differential refractometer temperature of 40.0° C. and sample injection volume of 100 μL. In addition, 3 parts by weight of a radiation-polymerizable compound in the form of 2,2-dimethoxy-2-phenylacetophenone were prepared based on 100 parts by weight of the carboxyl group-containing polymer. 5 parts by weight of a crosslinking agent in the form of a polyisocyanate-based crosslinking agent were prepared based on 100 parts by weight of the carboxyl group-containing polymer.

A resin solution for the adhesive layer 300 was prepared by blending the aforementioned carboxyl group-containing polymer, urethane acrylate, radiation-polymerizable compound and crosslinking agent. After coating this resin solution onto the base material layer 200 so that the thickness of the adhesive layer 300 after drying was 15 μm, the coated resin solution was dried for 5 minutes at 80° C. to obtain the desired adhesive tape 100.

<Evaluation of Adhesiveness to Adherend>

After allowing to stand at 23° C. for 7 days or more after preparation, the adhesive tape 100 was adhered to an adherend in the form of a semiconductor wafer. The adhesive strength of the adhesive tape 100 to the mirrored surface of the semiconductor wafer 20 minutes later was measured with a 180° peel test. The 180° peel test was carried out using a universal tester (trade name: Tensilon, A & D Co., Ltd.) under conditions of an environmental temperature of 23° C., environmental pressure of normal pressure and pulling speed of 300 ram/min. The mean value of the resulting adhesive strength chart was used as the adhesive strength of the adhesive layer 300 (cN/25 mm). A measured adhesive strength of 1000 cN/25 mm or more was evaluated with a ⊚, that of 500 cN/25 mm to less than 1000 cN/25 mm was evaluated with a ◯, and that of less than 500 cN/25 mm was evaluated with an X.

As a result of carrying out the aforementioned evaluation, the adhesive strength was 1600 cN/25 mm, and the adhesive strength of the adhesive tape 100 to the adherend was evaluated as ⊚ (refer to the following Table 1).

<Evaluation of Pickup and Adhesive Deposit>

After pressing a semiconductor wafer onto the adhesive tape 100 under conditions of 23° C. and allowing to stand for 20 minutes, the semiconductor wafer was diced to a size of 10 mm×10 mm. After dicing, the adhesive tape 100 was irradiated with ultraviolet light, the surface of the diced semiconductor wafers was suctioned with an vacuum-suctioning collet, and four needles at an interval of 4 mm were used to lift up the diced semiconductor wafers from the adhesive tape 100 by 500 μm to pick up the diced semiconductor wafers from the adhesive tape 100. The case of being able to pick up 99% or more of the diced semiconductor wafers was evaluated with a ⊚, that of 90% to less than 99% was evaluated with a ◯, and all other cases were evaluated with an X.

Moreover, an evaluation was also made of the occurrence of so-called adhesive deposit as to whether or not a portion of the adhesive that composes the adhesive layer 300 remains on the surface of the semiconductor wafer after peeling off the adhesive tape 100. More specifically, adhesive deposit on the surface of the semiconductor wafers where the adhesive tape 100 was adhered after dicing as well as adherence of adhesive scattered during dicing to the opposite side from the side where the adhesive tape 100 was adhered or on a lateral surface thereof were observed visually. The case of there being no occurrence of adhesive deposit or adherence of adhesive on the semiconductor wafers was evaluated with a ⊚, the occurrence of adhesive deposit or adherence of adhesive in 5% or less of all of the semiconductor wafers was evaluated with a ◯, and the occurrence of adhesive deposit or adherence of adhesive in more than 5% of all of the semiconductor wafers was evaluated with an X.

As a result of carrying out the aforementioned evaluations, 99% of the diced chips were able to be picked up and pickup was evaluated as ⊚. Since there was no occurrence of adhesive deposit or adherence of adhesive to the semiconductor wafers after dicing, adhesive deposit was also evaluated as ⊚ (refer to the following Table 1)

### Example 2

The adhesive tape 100 was obtained in the same manner as Example 1 with the exception of that indicated below. 50 parts by weight of urethane acrylate having a weight average molecular weight of 1800 and 6 functional groups (trade name: Miramer PU610, Miwon Specialty Chemical Co., Ltd.) were prepared based on 100 parts by weight of the carboxyl group-containing polymer for use as the curing component of the adhesive layer 300. In addition, 5 parts by weight of a crosslinking agent in the form of a polyisocyanate-based crosslinking agent were prepared based on 100 parts by weight of the carboxyl group-containing polymer.

This adhesive tape 100 was evaluated for adhesiveness to the adherend, pickup and adhesive deposit in the same manner as Example 1.

As a result, adhesive strength according to the present example was 1400 cN/25 mm, and adhesiveness of the adhesive tape 100 to the adherend was evaluated as ⊚. Since 100% of the diced chips were able to be picked up, pickup was evaluated as ⊚. Since there was no occurrence of adhesive deposit or adherence of adhesive to the diced semiconductor wafers, adhesive deposit was also evaluated as ⊚ (refer to the following Table 1)

### Example 3

A dicing tape was obtained in the same manner as Example 1 with the exception of that indicated below. 30 parts by weight of urethane acrylate having a weight average molecular weight of 1400 and 9 functional groups (trade name: UA-33H, Shin-Nakamura Chemical Co., Ltd.) were prepared based on 100 parts by weight of the carboxyl group-containing polymer for use as the curing component of the adhesive layer 300. In addition, 5 parts by weight of a crosslinking agent in the form of a polyisocyanate-based crosslinking agent were prepared based on 100 parts by weight of the carboxyl group-containing polymer.

This adhesive tape 100 was evaluated for adhesiveness to the adherend, pickup and adhesive deposit in the same manner as Example 1.

As a result, adhesive strength according to the present example was 2000 cN/25 mm, and adhesiveness of the dicing tape to the adherend was evaluated as ⊚. Since 96% of the diced chips were able to be picked up, pickup was evaluated as ◯. Since there was no occurrence of adhesive deposit or adherence of adhesive to the diced semiconductor wafers, adhesive deposit was also evaluated as ⊚ (refer to the following Table 1).

### Example 4

A dicing tape was obtained in the same manner as Example 1 with the exception of that indicated below. 70 parts by weight of urethane acrylate having a weight average molecular weight of 1400 and 9 functional groups (trade name: UA-33H, Shin-Nakamura Chemical Co., Ltd.) were prepared based on 100 parts by weight of the carboxyl group-containing polymer for use as the curing component of the adhesive layer 300. In addition, 5 parts by weight of a crosslinking agent in the form of a polyisocyanate-based crosslinking agent were prepared based on 100 parts by weight of the carboxyl group-containing polymer.

This adhesive tape 100 was evaluated for adhesiveness to the adherend, pickup and adhesive deposit in the same manner as Example 1.

As a result, adhesive strength according to the present example was 1200 cN/25 mm, and adhesiveness of the dicing tape to the adherend was evaluated as ⊚. Since 100% of the diced chips were able to be picked up, pickup was evaluated as ⊚. Since adhesive deposit or adherence of adhesive occurred to 2% of the diced semiconductor wafers, adhesive deposit was evaluated as ◯ (refer to the following Table 1).

### Example 5

A dicing tape was obtained in the same manner as Example 1 with the exception of that indicated below. 20 parts by weight of urethane acrylate having a weight average molecular weight of 1400 and 9 functional groups (trade name: UA-33H, Shin-Nakamura Chemical Co., Ltd.) were prepared based on 100 parts by weight of the carboxyl group-containing polymer for use as the curing component of the adhesive layer 300. In addition, 5 parts by weight of a crosslinking agent in the form of a polyisocyanate-based crosslinking agent were prepared based on 100 parts by weight of the carboxyl group-containing polymer.

This adhesive tape 100 was evaluated for adhesiveness to the adherend, pickup and adhesive deposit in the same manner as Example 1.

As a result, adhesive strength according to the present example was 2200 cN/25 mm, and adhesiveness of the dicing tape to the adherend was evaluated as ⊚. Since 92% of the diced chips were able to be picked up, pickup was evaluated as ◯. Since there was no occurrence of adhesive deposit or adherence of adhesive to the diced semiconductor wafers, adhesive deposit was evaluated as ⊚ (refer to the following Table 1).

### Example 6

A dicing tape was obtained in the same manner as Example 1 with the exception of that indicated below. 20 parts by weight of urethane acrylate having a weight average molecular weight of 1400 and 9 functional groups (trade name: UA-33H, Shin-Nakamura Chemical Co., Ltd.) were prepared based on 100 parts by weight of the carboxyl group-containing polymer for use as the curing component of the adhesive layer 300. In addition, 5 parts by weight of a crosslinking agent in the form of a polyisocyanate-based crosslinking agent were prepared based on 100 parts by weight of the carboxyl group-containing polymer.

This adhesive tape 100 was evaluated for adhesiveness to the adherend, pickup and adhesive deposit in the same manner as Example 1.

As a result, adhesive strength according to the present example was 900 cN/25 mm, and adhesiveness of the dicing tape to the adherend was evaluated as ◯. Since 100% of the diced chips were able to be picked up, pickup was evaluated as ⊚. Since adhesive deposit or adherence of adhesive occurred to 5% of the diced semiconductor wafers, adhesive deposit was evaluated as ◯(refer to the following Table 1).

### Example 7

A dicing tape was obtained in the same manner as Example 1 with the exception of that indicated below. A carboxyl group-containing polymer (ratio of number of ester groups to number of carboxyl groups: 98/2) produced using the same method as Example 1 was prepared instead of the carboxyl group-containing polymer of the adhesive layer 300. 50 parts by weight of urethane acrylate having a weight average molecular weight of 1400 and 9 functional groups (trade name: UA-33H, Shin-Nakamura Chemical Co., Ltd.) were prepared based on 100 parts by weight of the carboxyl group-containing polymer for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This adhesive tape 100 was evaluated for adhesiveness to the adherend, pickup and adhesive deposit in the same manner as Example 1.

As a result, adhesive strength according to the present example was 800 cN/25 mm, and adhesiveness of the dicing tape to the adherend was evaluated as ◯. Since 95% of the diced chips were able to be picked up, pickup was evaluated as ◯. Since adhesive deposit or adherence of adhesive occurred to 3% of the diced semiconductor wafers, adhesive deposit was also evaluated as ◯ (refer to the following Table 1).

### Comparative Example 1

A dicing tape was obtained in the same manner as Example 1 with the exception of that indicated below. 50 parts by weight of urethane acrylate having a weight average molecular weight of 467 and 4 functional groups (trade name: Kayarad T-1420 (T), Nippon Kayaku Co., Ltd.) were prepared based on 100 parts by weight of the carboxyl group-containing polymer for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This adhesive tape 100 was evaluated for adhesiveness to the adherend, pickup and adhesive deposit in the same manner as Example 1.

As a result, adhesive strength according to the present comparative example was 1900 cN/25 mm, and adhesiveness of the dicing tape to the adherend was evaluated as ⊚. Since 67% of the diced chips were able to be picked up, pickup was evaluated as X. Since adhesive deposit or adherence of adhesive occurred to 16% of the diced semiconductor wafers, adhesive transfer was evaluated as X (refer to the following Table 1).

### Comparative Example 2

A dicing tape was obtained in the same manner as Example 1 with the exception of that indicated below. 50 parts by weight of urethane acrylate having a weight average molecular weight of 20000 and 15 functional groups (trade name: Miramer SC2152, Miwon Specialty Chemical Co., Ltd.) were prepared based on 100 parts by weight of the carboxyl group-containing polymer for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This adhesive tape 100 was evaluated for adhesiveness to the adherend, pickup and adhesive deposit in the same manner as Example 1.

As a result, adhesive strength according to the present comparative example was 400 cN/25 mm, and adhesiveness of the dicing tape to the adherend was evaluated as X. Since 92% of the diced chips were able to be picked up, pickup was evaluated as ◯. Since there was no occurrence of adhesive transfer or adherence of adhesive to the diced semiconductor wafers, adhesive transfer was evaluated as ⊚ (refer to the following Table 1).

### Comparative Example 3

A dicing tape was obtained in the same manner as Example 1 with the exception of that indicated below. 50 parts by weight of urethane acrylate having a weight average molecular weight of 11000 and 3 functional groups (trade name: Miramer PU320, Miwon Specialty Chemical Co., Ltd.) were prepared based on 100 parts by weight of the carboxyl group-containing polymer for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This adhesive tape 100 was evaluated for adhesiveness to the adherend, pickup and adhesive deposit in the same manner as Example 1.

As a result, adhesive strength according to the present comparative example was 870 cN/25 mm, and adhesiveness of the dicing tape to the adherend was evaluated as ⊚. Since 73% of the diced chips were able to be picked up, pickup was evaluated as X. Since there was no occurrence of adhesive transfer or adherence of adhesive to the diced semiconductor wafers, adhesive transfer was evaluated as ⊚ (refer to the following Table 1).

### Comparative Example 4

A dicing tape was obtained in the same manner as Example 1 with the exception of that indicated below. An acrylic polymer (SK Dyne 1491H, Soken Chemical & Engineering Co., Ltd.) was prepared instead of the carboxyl group-containing polymer of the adhesive layer 300. 50 parts by weight of urethane acrylate having a weight average molecular weight of 1400 and 9 functional groups (trade name: UA-33H, Shin-Nakamura Chemical Co., Ltd.) were prepared based on 100 parts by weight of the carboxyl group-containing polymer for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This adhesive tape 100 was evaluated for adhesiveness to the adherend, pickup and adhesive deposit in the same manner as Example 1.

As a result, adhesive strength according to the present comparative example was 400 cN/25 mm, and adhesiveness of the dicing tape to the adherend was evaluated as X. Since 100% of the diced chips were able to be picked up, pickup was evaluated as ⊚. Since adhesive deposit or adherence of adhesive occurred to 10% of the diced semiconductor wafers, adhesive transfer was evaluated as X (refer to the following Table 1).

### Comparative Example 5

A dicing tape was obtained in the same manner as Example 1 with the exception of that indicated below. A silicon-based polymer (trade name: TSE3221S, Momentive Performance Materials, Inc.) was prepared instead of the carboxyl group-containing polymer of the adhesive layer 300. 50 parts by weight of urethane acrylate having a weight average molecular weight of 1400 and 9 functional groups (trade name: UA-33H, Shin-Nakamura Chemical Co., Ltd.) were prepared based on 100 parts by weight of the carboxyl group-containing polymer for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This adhesive tape 100 was evaluated for adhesiveness to the adherend, pickup and adhesive deposit in the same manner as Example 1.

As a result, adhesive strength according to the present comparative example was 340 cN/25 mm, and adhesiveness of the dicing tape to the adherend was evaluated as X. Since 95% of the diced chips were able to be picked up, pickup was evaluated as ◯. Since adhesive deposit or adherence of adhesive occurred to 25% of the diced semiconductor wafers, adhesive deposit was evaluated as X (refer to the following Table 1).

TABLE 1

| | | | | No. of | | | | |
|---|---|---|---|---|---|---|---|---|
| | | Ester groups/ | Molecular | functional | Content of | | | |
| | | carboxyl groups | weight of | groups of | radiation- | | | |
| | | of carboxyl | radiation- | radiation- | polymerizable | | | |
| | Main material | group-containing | polymerizable | polymerizable | compound | Adhesiveness | | Adhesive |
| | resin of adhesive | polymer | compound (Mw) | compound | (parts by wt.) | to adherend | Pickup | deposit |
| Ex. 1 | Carboxyl | 90/10 | 1400 | 9 | 50 | ⊚ | ⊚ | ⊚ |
| | group-containing | | | | | | | |
| | acrylic polymer | | | | | | | |
| Ex. 2 | Carboxyl | 90/10 | 1800 | 6 | 50 | ⊚ | ⊚ | ⊚ |
| | group-containing | | | | | | | |
| | acrylic polymer | | | | | | | |
| Ex. 3 | Carboxyl | 90/10 | 1400 | 9 | 30 | ⊚ | ◯ | ⊚ |
| | group-containing | | | | | | | |
| | acrylic polymer | | | | | | | |
| Ex. 4 | Carboxyl | 90/10 | 1400 | 9 | 70 | ⊚ | ⊚ | ◯ |
| | group-containing | | | | | | | |
| | acrylic polymer | | | | | | | |
| Ex. 5 | Carboxyl | 90/10 | 1400 | 9 | 20 | ⊚ | ◯ | ◯ |
| | group-containing | | | | | | | |
| | acrylic polymer | | | | | | | |
| Ex. 6 | Carboxyl | 90/10 | 1400 | 9 | 80 | ◯ | ⊚ | ◯ |
| | group-containing | | | | | | | |
| | acrylic polymer | | | | | | | |
| Ex. 7 | Carboxyl | 98/2 | 1400 | 9 | 50 | ◯ | ◯ | ◯ |
| | group-containing | | | | | | | |
| | acrylic polymer | | | | | | | |
| Comp. | Carboxyl | 90/10 | 467 | 4 | 50 | ⊚ | X | X |
| Ex. 1 | group-containing | | | | | | | |
| | acrylic polymer | | | | | | | |
| Comp. | Carboxyl | 90/10 | 20000 | 5 | 50 | X | ◯ | ⊚ |
| Ex. 2 | group-containing | | | | | | | |
| | acrylic polymer | | | | | | | |
| Comp. | Carboxyl | 90/10 | 11000 | 3 | 50 | ⊚ | X | ⊚ |
| Ex. 3 | group-containing | | | | | | | |
| | acrylic polymer | | | | | | | |
| Comp. | Acrylic polymer | 100/0 | 1400 | 9 | 50 | X | ⊚ | X |
| Ex. 4 | | | | | | | | |
| Comp. | Silicon-based | — | 1400 | 9 | 50 | X | ◯ | X |
| Ex. 5 | polymer | | | | | | | |

In the adhesive tapes 100 according to Examples 1 and 2, the evaluations of adhesiveness to the adherend, adhesive deposit and pickup were all ⊚. In addition, in the adhesive tapes 100 of Examples 3 and 4, evaluations for two of the parameters were ⊚ and that for the other parameter was ◯, in the adhesive tapes 100 of Examples 5 and 6, evaluation for one of the parameters was ⊚ and those for the other two parameters were ◯, and in the adhesive tape 100 of Example 7, all evaluations were ◯. In contrast, in the dicing tapes according to Comparative Examples 1 to 5, at least one of the evaluations for adhesiveness to the adherend, adhesive deposit and pickup was X.

### Example A1

### Production of Dicing Tape

A dicing (adhesive) tape 100 was obtained in the same manner as Example 1 with the exception of that indicated below.

Urethane acrylate having a weight average molecular weight of 3200 g/mol and 10 functional groups (trade name: Miramer MU9500, Miwon Specialty Chemical Co., Ltd.) was prepared for use as the curing component of the adhesive layer 300.

<Evaluation of Adhesiveness to Adherend>

Adhesiveness to the adherend was evaluated in the same manner as Example 1 with the exception of that indicated below.

Measured adhesive strength of 500 cN/25 mm or more was evaluated with a ◯, and that of less than 500 cN/25 mm was evaluated with an X.

<Evaluation of Adhesive Deposit>

An evaluation was made of the occurrence of so-called adhesive deposit as to whether or not a portion of the adhesive that composes the adhesive layer 300 remains on the surface of the semiconductor wafer after peeling off the dicing tape 100. More specifically, adhesive remaining on the surface of the semiconductor wafers where the dicing tape 100 was adhered after peeling off the dicing tape 100 as well as adherence of adhesive scattered during dicing to the opposite side from the side where the dicing tape 100 was adhered or on a lateral surface thereof were observed visually. The case of there being no occurrence of adhesive deposit or adherence of adhesive on the semiconductor wafers was evaluated with a ◯, while the occurrence of adhesive deposit or adherence of adhesive was evaluated with an X.

As a result of carrying out the aforementioned evaluations, adhesive strength was 1300 cN/25 mm, and adhesiveness of the dicing tape 100 to the adherend was evaluated as ◯. Since there was no occurrence of adhesive deposit in the semiconductor wafers peeled from the adhesive tape 100, adhesive deposit was evaluated as ◯ (refer to the following Table 2).

<Evaluation of Pickup>

Pickup was evaluated in the same manner as Example 1 with the exception of that indicated below.

The case of being able to pick up 95% or more of the diced semiconductor wafers was evaluated with a ◯, and all other cases were evaluated with an X.

As a result of carrying out the aforementioned evaluation, 99% of the diced chips were able to be picked up and pickup was evaluated as ◯ (refer to the following Table 2)

### Example A2

The dicing tape 100 was obtained in the same manner as Example A1 with the exception of that indicated below. Urethane acrylate having a weight average molecular weight of 14000 g/mol and 15 functional groups (trade name: Miramer MU9510, Miwon Specialty Chemical Co., Ltd.) was prepared for use as the curing component of the adhesive layer 300. In addition, 7 parts by weight of a crosslinking agent in the form of a polyisocyanate-based crosslinking agent were prepared based on 100 parts by weight of the carboxyl group-containing polymer.

This dicing tape 100 was evaluated for adhesiveness to the adherend, adhesive deposit and pickup in the same manner as Example A1.

As a result, adhesive strength according to the present example was 900 cN/25 mm, and adhesiveness of the dicing tape 100 to the adherend was evaluated as ◯. Since adhesive deposit to the semiconductor wafers peeled from the dicing tape 100 was not observed, adhesive deposit was evaluated as ◯. Since 100% of the diced chips were able to be picked up, pickup was evaluated as ◯ (refer to the following Table 2)

### Comparative Example A1

Dicing tape was obtained in the same manner as Example A1 with the exception of that indicated below. Urethane acrylate having a weight average molecular weight of 467 g/mol and 4 functional groups (trade name: Kayarad T-1420 CT), Nippon Kayaku Co., Ltd.) was prepared for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This dicing tape was evaluated for adhesiveness to the adherend, adhesive deposit and pickup in the same manner as Example A1.

As a result, adhesive strength according to the present comparative example was 1900 cN/25 mm, and adhesiveness of the dicing tape to the adherend was evaluated as ◯. Since adhesive deposit to the semiconductor wafers peeled from the dicing tape occurred, adhesive deposit was evaluated as X. Since 67% of the diced chips were able to be picked up, pickup was evaluated as X (refer to the following Table 2)

### Comparative Example A2

Dicing tape was obtained in the same manner as Example A1 with the exception of that indicated below. Urethane acrylate having a weight average molecular weight of 20787 g/mol and 15 functional groups (trade name: Miramer SC2152, Miwon Specialty Chemical Co., Ltd.) was prepared for use as the curing component of the adhesive layer 300. 7 parts by weight of a polyisocyanate-based crosslinking agent were prepared based on 100 parts by weight of the carboxyl group-containing polymer for use as the crosslinking agent of the adhesive layer 300.

This dicing tape was evaluated for adhesiveness to the adherend, adhesive deposit and pickup in the same manner as Example A1.

As a result, adhesive strength according to the present comparative example was 400 cN/25 mm, and adhesiveness of the dicing tape to the adherend was evaluated as X. Since adhesive deposit to the semiconductor wafers peeled from the dicing tape did not occur, adhesive deposit was evaluated as ◯. Since 100% of the diced chips were able to be picked up, pickup was evaluated as ◯ (refer to the following Table 2).

### Comparative Example A3

Dicing tape was obtained in the same manner as Example A1 with the exception of that indicated below. Urethane acrylate having a weight average molecular weight of 11000 g/mol and 3 functional groups (trade name: Miramer PU320, Miwon Specialty Chemical Co., Ltd.) was prepared for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This dicing tape was evaluated for adhesiveness to the adherend, adhesive deposit and pickup in the same manner as Example A1.

As a result, adhesive strength according to the present comparative example was 870 cN/25 mm, and adhesiveness of the dicing tape to the adherend was evaluated as ◯. Since adhesive deposit to the semiconductor wafers peeled from the dicing tape did not occur, adhesive deposit was evaluated as ◯. Since 73% of the diced chips were able to be picked up, pickup was evaluated as X (refer to the following Table 2)

### Comparative Example A4

Dicing tape was obtained in the same manner as Example A1 with the exception of that indicated below. An acrylic polymer (trade name: SK Dyne 1491H, Soken Chemical & Engineering Co., Ltd.) was prepared for use as the carboxyl group-containing polymer of the adhesive layer 300. Urethane acrylate having a weight average molecular weight of 8000 g/mol and 10 functional groups (trade name: Miramer MU9500, Miwon Specialty Chemical Co., Ltd.) was prepared for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This dicing tape was evaluated for adhesiveness to the adherend, adhesive deposit and pickup in the same manner as Example A1.

As a result, adhesive strength according to the present comparative example was 300 cN/25 mm, and adhesiveness of the dicing tape to the adherend was evaluated as X Since adhesive deposit to the semiconductor wafers peeled from the dicing tape occurred, adhesive deposit was evaluated as X. Since 100% of the diced chips were able to be picked up, pickup was evaluated as ◯ (refer to the following Table 2)

### Comparative Example A5

Dicing tape was obtained in the same manner as Example A1 with the exception of that indicated below. A silicon-based polymer (trade name: TSE3221S, Momentive Performance Materials, Inc.) was prepared for use as the carboxyl group-containing polymer of the adhesive layer 300. Urethane acrylate having a weight average molecular weight of 8000 g/mol and 10 functional groups (trade name: Miramer MU9500, Miwon Specialty Chemical Co., Ltd.) was prepared for use as the curing component of the adhesive layer 300. 5 parts by weight of a polyisocyanate-based crosslinking agent were prepared based on 100 parts by weight of the carboxyl group-containing polymer for use as the crosslinking agent of the adhesive layer 300.

This dicing tape was evaluated for adhesiveness to the adherend, adhesive deposit and pickup in the same manner as Example A1.

As a result, adhesive strength according to the present comparative example was 340 cN/25 mm, and adhesiveness of the dicing tape to the adherend was evaluated as X. Since adhesive deposit to the semiconductor wafers peeled from the dicing tape occurred, adhesive deposit was evaluated as X. Since 100% of the diced chips were able to be picked up, pickup was evaluated as ◯ (refer to the following Table 2)

TABLE 2

| | | | No. of | | | | |
|---|---|---|---|---|---|---|---|
| | | Molecular | functional | | | | |
| | | weight of | groups of | Amount of | | | |
| | Main material | radiation- | radiation- | crosslinking | | | |
| | resin of adhesive | polymerizable | polymerizable | agent (parts by | Adhesiveness to | Adhesive | |
| | layer | compound (Mw) | compound | weight) | adherened | deposit | Pickup |
| Ex. A1 | Carboxyl | 3200 | 10 | 5 | ◯ | ◯ | ◯ |
| | group-containing | | | | | | |
| | acrylic polymer | | | | | | |
| Ex. A2 | Carboxyl | 14000 | 15 | 7 | ◯ | ◯ | ◯ |
| | group-containing | | | | | | |
| | acrylic polymer | | | | | | |
| Comp. Ex. A1 | Carboxyl | 467 | 4 | 5 | ◯ | X | X |
| | group-containing | | | | | | |
| | acrylic polymer | | | | | | |
| Comp. Ex. A2 | Carboxyl | 20787 | 15 | 7 | X | ◯ | ◯ |
| | group-containing | | | | | | |
| | acrylic polymer | | | | | | |
| Comp. Ex. A3 | Carboxyl | 11000 | 3 | 5 | ◯ | ◯ | X |
| | group-containing | | | | | | |
| | acrylic polymer | | | | | | |
| Comp. Ex. A4 | Acrylic polymer | 8000 | 10 | 5 | X | X | ◯ |
| Comp. Ex. A5 | Silicon-based | 8000 | 10 | 5 | X | X | ◯ |
| | polymer | | | | | | |

In the dicing tapes 100 of Examples A1 and A2, the evaluations of adhesiveness to the adherend, adhesive deposit and pickup were all ◯. In contrast, in the dicing tapes of Comparative Examples A1 to A5, at least one of the evaluations of adhesiveness to the adherend, adhesive deposit and pickup was X.

### INDUSTRIAL APPLICABILITY

The adhesive tape for semiconductor wafer processing of the present invention is an adhesive tape for processing semiconductor wafers and the like that is able to reduce the amount of adhesive remaining on the surface of an adherend after peeling off the tape.

### BRIEF DESCRIPTION OF THE REFERENCE SYMBOLS

100 Dicing tape (adhesive tape for semiconductor wafer processing)
200 Base material layer (base layer)
300 Adhesive layer

1. An adhesive tape for semiconductor wafer processing, comprising a base material layer and an adhesive layer formed on at least one side of the base material layer, wherein
the adhesive layer contains a carboxyl group-containing polymer, a radiation-polymerizable compound and a crosslinking agent,
the weight average molecular weight of the radiation-polymerizable compound is 500 or more and 14000 or less, the number of functional groups of the radiation-polymerizable compound is 5 or more, and
the content of the crosslinking agent is 3 parts by weight to 14 parts by weight based on 100 parts by weight of the carboxyl group-containing polymer.

2. The adhesive tape for semiconductor wafer processing according to claim 1, wherein the weight average molecular weight of the radiation-polymerizable compound is 1000 or more and 14000 or less, and the number of functional groups is 10 or more.

3. The adhesive tape for semiconductor wafer processing according to claim 1, wherein the carboxyl group-containing polymer further contains ester group, and
the ratio of the number of ester groups to the number of carboxyl groups in the carboxyl group-containing polymer (ester groups/carboxyl groups) is 80/20 to 95/5.

4. The adhesive tape for semiconductor wafer processing according to claim 1, wherein the weight average molecular weight of the radiation-polymerizable compound is 500 to 3000 and the number of functional groups is 15 or less.

5. The adhesive tape for semiconductor wafer processing according to claim 1, wherein the functional groups are vinyl groups.

6. The adhesive tape for semiconductor wafer processing according to claim 1, wherein the content of the radiation-polymerizable compound is 30 parts by weight to 70 parts by weight based on 100 parts by weight of the carboxyl group-containing polymer.

7. The adhesive tape for semiconductor wafer processing according to claim 1, wherein the radiation-polymerizable compound is urethane acrylate.

8. The adhesive tape for semiconductor wafer processing according to claim 1, wherein the crosslinking agent contains an isocyanate group.

9. The adhesive tape for semiconductor wafer processing according to claim 1, wherein the carboxyl group-containing polymer is a copolymer of an acrylic acid ester and acrylic acid.
